(19) United States
(12) Patent Application Publication
(10) Pub. No.: US 2013/0062875 A1
(43) Pub. Date: Mar. 14, 2013

(54) FIBROUS INSERT CONSISTING OF A SINGLE LAYER AND EQUIPPED WITH A CONTACTLESS COMMUNICATION ELECTRONIC DEVICE

(71) Applicant: Arjowiggins Security, Boulogne Billancourt (FR)

(72) Inventors: Thibaut Le Loarer, Pommier de Beaurepaire (FR); Pascal Marlin, Coulommiers (FR)

(73) Assignee: ARJOWIGGINS SECURITY, Boulogne Billancourt (FR)

(21) Appl. No.: 13/663,103

(22) Filed: Oct. 29, 2012

Related U.S. Application Data
(63) Continuation of application No. PCT/IB2011/051752, filed on Apr. 21, 2011.

(30) Foreign Application Priority Data
Apr. 28, 2010 (FR) 1001815

(51) Int. Cl. B42D 15/00; H05K 13/00; H05K 13/04

(52) U.S. Cl. CPC B42D 15/00; H05K 13/046; H05K 13/0023
USPC 283/83; 29/592.1; 29/601; 29/600

(57) ABSTRACT

The invention relates to a flat insert intended for being inserted in a security document, which includes a fibrous substrate (2) formed as a single layer having a cavity (5) and an electronic device (3) having contactless communication, housed in said cavity. Said cavity is in communication with a single surface of the fibrous substrate (2) and includes, in the cross-section thereof, a peripheral shoulder (13) for housing said electronic device in said cavity without generating a thickened portion of the insert, said fibrous substrate (2) including synthetic fibres.

### CROSS REFERENCE TO RELATED APPLICATIONS

This application is a continuation of PCT Patent Application No. PCT/IB2011/051752, titled “FIBROUS INSERT CONSISTING OF A SINGLE LAYER AND EQUIPPED WITH A CONTACTLESS COMMUNICATION ELECTRONIC DEVICE,” filed Apr. 21, 2011, which claims priority to French Patent Application No. 10 01815 filed on Apr. 28, 2010, which is herein incorporated by reference.

### FIELD OF INVENTION

The present invention relates to a flat insert intended to be inserted in a security document such as a passport, an identity card, a driving license, etc. In particular, the insert comprises a support including a contactless communication electronic device housed in a cavity of the support. For example, the electronic device is a radiofrequency identification (RFID) device.

### BACKGROUND

This type of insert provided with a contactless communication electronic device is being increasingly used in security documents such as, for example, documents identifying individuals. In practice, the electronic device generally contains in its memory data relating to the holder of the document which are often encrypted. Such inserts therefore constitute a security means which is difficult to forge by a forger. There is therefore an increasing need for inserts for this type of document.

Conventionally, the cavity intended to receive the electronic device may be formed by a mechanical milling, facing or boring method, by perforation or by the use of a laser.

These mechanical methods mainly consist in rotating a tool which comes into contact with the surface of the insert and forms the cavity. The rotation of the tool results in a cavity bottom which is usually not flat and therefore not suitable for receiving a chip which is substantially flat. Furthermore, such a method implemented on a fibrous support causes a ripping out of the fibres and a deformation of the cavity.

The perforation of the insert support, for example with a hollow punch tool, forms a cavity passing through the support. An insert provided with such a cavity does not provide optimum protection of the chip which is accessible and can therefore be subjected to stresses and/or attacks, notably mechanical or chemical.

The formation of a cavity by means of a laser is relatively lengthy and costly and does not make it possible to achieve sufficient depths to house the chip in the support of the insert without increasing the thickness. Furthermore, the laser burns, damages and blackens the material of the support which causes the material of the support to be embrittled at the level of the cavity.

The document WO2005073907 discloses an insert made of plastic material equipped with a contactless communication electronic device. The insert consists of at least two layers to compensate for the thickness of the electronic device. One of the two layers is provided with a cavity passing through the layer and intended to partially house the electronic device. The other part of the electronic device is housed by compression in the other layer so as to obtain an electronic device whose thickness is compensated by the two layers. The method for obtaining this insert is relatively long and costly since it involves a large number of steps. Firstly, the layers are fabricated, one of the layers must then be punched, the electronic device is placed in the cavity, and finally the two layers must be laminated according to the register mark to form the insert.

The document WO 2009046791 discloses an insert made of thermoplastic material which consists of a single layer. The insert is provided with a contactless communication electronic device housed in a through cavity which is formed in the insert. Such an insert presents a certain number of drawbacks. On the one hand, the thermoplastic material is certain to melt under the action of heat which can be very problematical given that the mechanical method used to form the cavity involves raising the temperature in the cavity formation area. Such a material therefore has a tendency to creep randomly during the cavity forming operation. The result of this is that the cavity exhibits deformations and is therefore not suitable for housing the electronic device. Also, with such an insert, the electronic device is not protected from external attacks and stresses, notably mechanical and chemical, since it is accessible and visible on both faces of the insert.

### SUMMARY OF INVENTION

The aim of the invention is therefore to propose an insert comprising a contactless communication electronic device which does not present the abovementioned drawbacks. Another aim of the invention is to propose an insert which is simple and inexpensive to fabricate.

To this end, the subject of the invention is a flat insert intended to be inserted into a security document, comprising a fibrous support consisting of a single layer provided with a cavity and a contactless communication electronic device housed in said cavity, said cavity opens out onto a single face of the support and it comprises, in cross section, a peripheral shoulder to house said electronic device in said cavity without increasing the thickness of the insert.

The insert according to the invention is particularly well protected from external attacks and stresses, notably mechanical, since the electronic device is housed in a cavity that opens out onto only one face, which means that the other face is protected by the fibrous material of the support. Furthermore, this arrangement makes it possible to secure the electronic device in the bottom of the cavity. Conversely, an electronic device housed in a cavity obtained by perforation would require the device to be held in place; for example, before lamination with another layer serving as support.

According to a particular embodiment of the invention, the contactless communication electronic device is a module chip comprising an encapsulated chip and a connection support on which the encapsulated chip rests for the connection between said chip and an antenna, the connection support being positioned in said peripheral shoulder of the cavity and the encapsulated chip being positioned in a bottom of the cavity. The peripheral shoulder is situated between the face of the support on which the cavity opens out and the bottom of the cavity housing the encapsulated chip. Consequently, the module chip is completely inserted into the cavity and flush with the open face of the support. The insertion of the module chip into the support does not result in any extra thickness. The thickness of the insert is therefore constant.

In particular, the electronic device is selected from the module chips of the micromodule MOA2, MOB2, MOA4, MOB4, MOA6 and MOB6 types marketed by the company PHILIPS, and of the MCC2 and MCC8 types marketed by the company INFINEON, and of the CID type marketed by the company EM MICROELECTRONIC, and of the Cubit, IOA2, EOA2, EOA8, EOA9, FCP3 and NSL-1 types.

The module chips, for example of the MOx, MOB2, MOA2, MOB4, MOA4, MOB6 or MOA6 type marketed by the company Philips are very widely used in applications on electronic passports and chip cards because of their long term mechanical stability. They respectively have a thickness of 390 microns for the MOA2 and the MOB2, 320 microns for the MOA4 and MOB4 and 260 microns for the MOA6 and MOB6. The MOA2 and MOA4 module chips have a surface area which is generally less than 4 mm² whereas the MOB2 and MOB4 module chips have a surface area generally greater than 4 mm².

As a general rule, a module chip comprises a microcircuit chip encapsulated in an insulating package provided with an opening at one end. The microcircuit chip is coated with a liquefied plastic product and held in a mould to allow for the plastic to harden. The opening in the package enables the chip to be connected to a connection support or metallic connection grid extending beyond the package. This connection support is cut and linked to the encapsulated chip so as to form terminals for connection to an antenna. The encapsulated microcircuit chip part of the module chip is also called “potting” and the connection support is called “lead frame” (connection grid).

In cross section, the module chip is in the form of a “T”, with the base of the “T” shape, less wide, corresponding to the encapsulated microcircuit chip and the top of the “T” shape, wider, corresponding to the connection support.

According to another particular embodiment of the invention, the insert comprises a wired or screen-printed antenna positioned on the face of the support on which the cavity opens out, said antenna being provided with two ends connected to the connection support for a contactless communication.

The wired or screen-printed antenna is arranged in a coil to form at least one turn.

According to another particular embodiment of the invention, the insert includes one or more of the following characteristics:
the fibrous support is formed by at least 30% natural fibres such as cellulosic fibres and/or cotton fibres with a lower proportion of short fibres than of long fibres,
the fibrous support comprises a binder selected from the thermoplastic polymers with a Tg of between −25° C. and 40° C., the binder is preferably precipitated en masse and preferably selected from a butadiene styrene copolymer, an acrylic polymer, a vinyl acetate and their copolymers, a latex, a starch compound, a mineral filler compound or a mixture of the latter,
the fibrous support includes a softening agent preferably selected from glycerin, urea or urea nitrate,
the fibrous support comprises between 8 and 15% synthetic fibres, by weight, in the fibrous base of the support, for example, the synthetic fibres are selected from thermoplastic materials such as a polyamide, a polyester, a polyolefin and/or a mixture of such fibres,
the fibrous support comprises a filler selected from mineral fillers, notably carbonates, in particular of calcium, talc, kaolin, aluminium hydrate, titanium dioxide, sodium silicate and their mixtures, the filler preferably being an absorbent filler having an absorption capacity greater than or equal to 30 ml/100 g.

The invention extends to a security document such as a passport, an identity card, a driving license, an interactive playing or trading card, a payment means, notably a payment card, a purchase slip or a voucher, a transport card, a loyalty card, a service card or a subscription card, including the insert. In the case of the passport, the cover and/or the booklet can be equipped with the insert.

The invention also extends to a method for fabricating a flat insert intended to be inserted into a security document, the method comprising steps consisting in:
providing a fibrous support,
forming a cavity in said support by compression by means of a part having a shoulder so that said cavity opens out onto a single face of the support and that it has, in cross section, a peripheral shoulder,
housing an electronic device in said cavity without increasing the thickness of the insert.

The insert obtained by such a fabrication method is equipped with a cavity that opens out onto a single face. It therefore does not pass through the support from side to side. This cavity therefore does not pass through the support of the insert. The insert obtained by the fabrication method according to the invention is thus protected from external attacks and stresses and held in place in the bottom of the cavity.

The cavity produced in the fibrous support has, in cross section, a “T” shape corresponding to that of the electronic device. Furthermore, the thickness of the support is preferably greater than the thickness of the electronic device so that the insert with the electronic device in the cavity has a constant thickness over its entire surface.

According to a particular embodiment of the invention, the step for forming said cavity in said support is performed by repeated compressions at an ultrasound frequency by means of the part having a shoulder. Preferably, the ultrasound frequency is between 20 kHz and 1 MHz.

According to another particular embodiment of the invention, the step for forming said cavity in said support is performed by thermocompression or by stamping.

According to yet another particular embodiment of the invention, there is provided an electronic device which is a module chip comprising an encapsulated chip and a connection support on which the chip rests for the connection between said chip and an antenna. The method also comprises a step consisting in positioning the connection support in said peripheral shoulder of the cavity and the encapsulated chip in a bottom of the cavity.

According to yet another particular embodiment of the invention, the method also comprises a step consisting in positioning a wired or screen-printed antenna on the face of the support on which the cavity opens out, said antenna being provided with two ends connected to the connection support for a contactless communication.

According to another particular embodiment of the invention, the method comprises one or more of the following steps:
providing the fibrous support with at least 30% natural fibres such as cellulosic fibres and/or cotton fibres with a lower proportion of short fibres than of long fibres,
providing the fibrous support with a binder selected from the thermoplastic polymers with a Tg of between −25° C. and 40° C., the binder is preferably precipitated en masse and preferably selected from a butadiene styrene copolymer, an acrylic polymer, a vinyl acetate and their copolymers, a latex, a starch compound, a mineral filler compound or a mixture of the latter,
providing the fibrous support with a softening agent preferably selected from glycerin, urea or urea nitrate,
providing the fibrous support with between 8 and 15% synthetic fibres, by weight, in the fibrous base, for example the synthetic fibres are selected from thermoplastic materials such as a polyamide, a polyester, a polyolefin and/or a mixture of such fibres,
providing the fibrous support with a filler selected from mineral fillers, notably carbonates, in particular of calcium, talc, kaolin, aluminium hydrate, titanium dioxide, sodium silicate and their mixtures, the filler preferably being an absorbent filler having an absorption capacity greater than or equal to 30 ml/100 g.

These characteristics of the fibrous support confer upon the insert a compressibility that is particularly suited to steps of repeated compressions at an ultrasound frequency. This is because, with such a fibrous support, it is possible according to the invention to produce a cavity with a depth that is sufficient to house the electronic device without the material of the support being deformed on the face on which the cavity does not open out. The support remains flat on this face.

An exemplary embodiment of the invention is described in more detail hereinbelow and illustrated by the figures. This description is given solely as an indication and is in no way limiting on the invention.

### BRIEF DESCRIPTION OF THE DRAWINGS

FIG. 1 schematically illustrates an insert according to the invention seen from above.

FIG. 2 schematically illustrates the insert according to the invention in a partial cross-sectional view along the axis A-A of FIG. 1.

FIGS. 3a) to d) schematically illustrate the various steps of the method for fabricating the insert according to the invention with the fibrous support seen in partial cross section.

### DETAILED DESCRIPTION OF THE PREFERRED EMBODIMENT

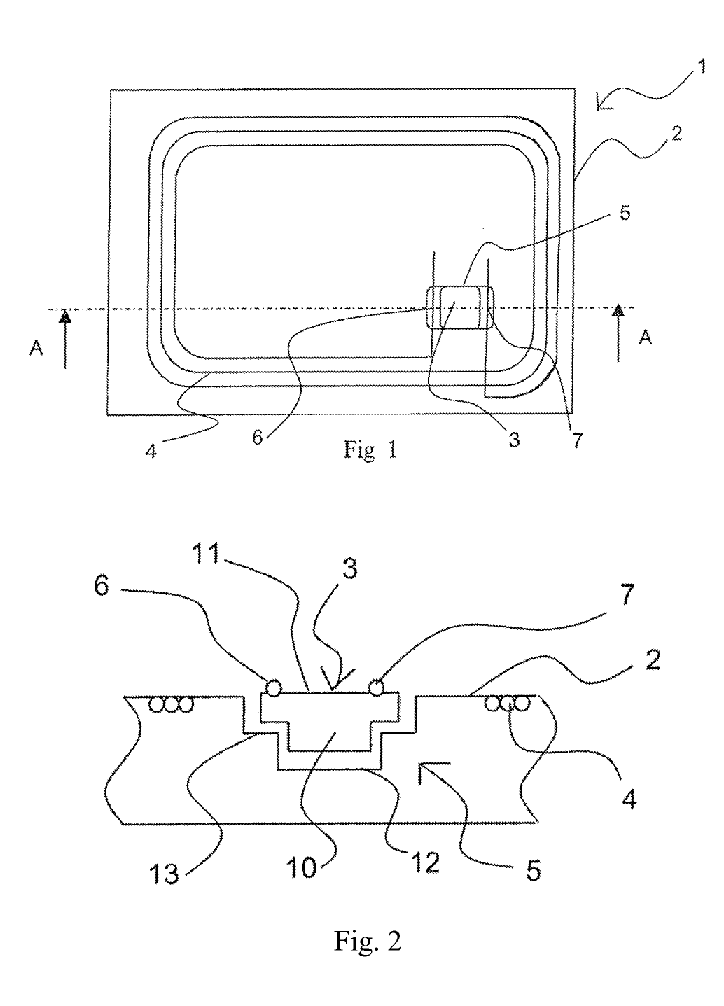

FIG. 1 shows a flat insert 1 according to the invention mainly comprising a fibrous support 2, a contactless communication electronic device 3 and an antenna 4.

The fibrous support 2 consists of a single layer and is provided with a cavity 5 capable of receiving the contactless communication electronic device 3 without increasing the thickness of the insert.

In the exemplary embodiment of FIGS. 1 and 2, the antenna 4 is a wired antenna, for example consisting of a copper wire surrounded by an insulating sheath except at its connection ends 6 and 7. As illustrated in FIG. 1, the antenna 4 is deposited on a face of the fibrous support 2 so as to form a plurality of concentric turns around the electronic device to which the connection ends 6 and 7 of the antenna 4 are soldered. The antenna and the device connected together form a transponder and the duly assembled insert 1 is capable of communicating with radiofrequency signals, for example with an external reader, by virtue of the electronic device 3 which generates or receives signals via the antenna 4. Alternatively, the antenna may be obtained by depositing a conductive ink using a screen-printing method on the face of the support of the insert.

FIG. 2 shows the details of the insert 1 according to the invention with the electronic device 3 inserted into the cavity 5 and the antenna 4 connected to the electronic device 3.

The electronic device 3 is preferably a module chip comprising an encapsulated microcircuit chip 10 and a connection support 11. The encapsulated chip 10 is fixed to the connection support 11 so as to form a “T”. The base of the “T” shape, less wide, corresponds to the encapsulated chip 10, and the top of the “T” shape, wider, corresponds to the connection support 11.

In particular, the electronic device is selected from the module chips of the MOA2, MOB2, MOA4, MOB4, MOA6 and MOB6 types marketed by the company PHILIPS.

In the case of an MOB4 module chip, the thickness of the encapsulated chip is approximately 200 microns and for an MOB6 module chip approximately 130 microns. For these two module chips, the connection support has a thickness of approximately 130 microns. The connection support 11 has a greater length than the encapsulated chip 10 which causes the “T” shape in cross section. Their widths are substantially equivalent.

The cavity 5 has, in cross section, a bottom 12 and a peripheral shoulder 13. The peripheral shoulder 13 is situated between the face of the support 2 on which the cavity 5 opens out, the top face in the example of FIG. 2, and the bottom 12 of the cavity housing the encapsulated chip 10. The dimensions of the cavity 5 substantially correspond to those of the module chip 3 so as to facilitate the insertion of the latter.

Furthermore, an adhesive may be deposited on the peripheral shoulder 13 of the cavity 5 to securely attach the fibrous support 2 and the module chip 3 together.

FIG. 2 shows that the connection support 11 of the module chip 3 is flush with the surface of the support. Consequently, the module chip 3 is entirely housed in the support 2 and the insert 1 according to the invention has a constant thickness over its entire surface. As detailed below, the constant thickness of the insert makes the detection of the module chip more difficult, thus strengthening the security of the security document in which the insert is positioned.

Furthermore, with such an arrangement and a thickness of the support 2 greater than that of the chip 3, the cavity 5 opens out only onto one face of the flat support 2; it does not pass through the support. The module chip 3 is therefore protected and held in place on the other face by a layer of fibrous material.

The antenna 4 illustrated in FIG. 2 is, for example, deposited in the support 2 by a thermocompression method or by an ultrasound method. The antenna 4 therefore penetrates into the fibrous support 2 to be securely attached thereto and does not increase the thickness of the insert 1. Because of this, it is fully protected and the insert according to the invention can be easily manipulated.

The conductive ends 6 and 7 of the antenna 4 are respectively soldered to two terminals electrically insulated from the connection support 11 of the module chip 3.

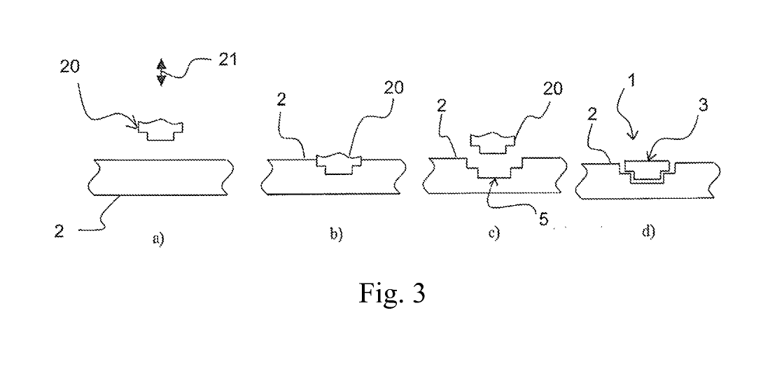

FIG. 3 illustrates, by four steps a) to d), the method according to the invention for fabricating a flat insert intended to be inserted in a security document.

In the first step of the method, a fibrous support is provided, obtained by means of a flat-table or round-shaped paper machine. Preferably, the fibrous support consists of at least 30% natural fibres such as cellulosic fibres and/or cotton fibres with a lower proportion of short fibres than of long fibres.

Preferably, the fibrous base of the support 2 also includes synthetic fibres. For example, the synthetic fibres are selected from fibres of a thermoplastic material, notably a polyamide, a polyester, a polyolefin and/or a mixture of such fibres.

The fibrous base preferably comprises between 8 and 15% synthetic fibres, by weight in the fibrous base.

The content by weight of synthetic fibres in the fibrous base can be evaluated, for example, by a three-dimensional measurement by stereology on two-dimensional cuts using a scanning electron microscope.

The use of synthetic fibres in the fibrous base provides the following properties:

high resistance to tearing and pulling force, flexibility and dimensional stability, which avoids too great a dimensional variation of the support and an unacceptable modification of the operating frequencies of the electronic device. Advantageously, the presence of such synthetic fibres facilitates the compression of the fibrous support 2 by displacement of the synthetic fibres without creep or deformation which is particularly suited to the formation of the cavity. The insertion of the antenna by thermocompression or by ultrasound is also facilitated.

Preferably, the fibrous base of the support 2 also includes a binder. For example, the binder may be a butadiene styrene copolymer, an acrylic polymer, a vinyl acetate and their copolymers, a latex, a starch compound, a mineral filler compound or a mixture of the latter. The binder has a glass transition temperature Tg of between −25° C. and 40° C., preferably 5° C. A particularly suitable fibrous base comprises an acrylic latex, urea nitrate, 15% synthetic fibres, for example based on 7.5% PET and 7.5% PA, with a length of 6 mm and a diameter of 1.7 dtex, 85% natural fibres, for example cellulose-based, including 80% long fibres and 20% short fibres, and 13% by weight of kaolin and approximately 5% titanium dioxide TiO2.

The binder of the fibrous base is, for example, introduced into the fibrous base by surfacing, for example by means of a gluing, or “size”, press. Alternatively, the fibres of the fibrous base are bound with a binder precipitated en masse.

The binder of the fibrous base is possibly combined with a softening agent. The latter can be selected from glycerin, urea or urea nitrate.

The presence of a flexible binder in the mass or on the surface of the flexible fibrous base and possibly of a softening agent imparts the following properties: flexibility, internal cohesion to give the insert sufficient resistance to delamination, pore-filling effect to keep the surface layer based on coating binder and fillers on the surface of the flexible support.

Preferably, the fibrous base of the support 2 also includes fillers. For example, the fillers are selected from mineral fillers, notably carbonates, in particular of calcium, talc, kaolin, aluminium hydrate, titanium dioxide, sodium silicate and their mixtures. The fillers are preferably absorbent fillers having an absorption capacity greater than or equal to 30 ml/100 g. The fibrous base may include between 8 and 20% by weight of mineral filler. Too great a quantity of filler, for example >25%, may not be suited to compression at an ultrasound frequency because the fillers “absorb” these frequencies which are not then transmitted to the fibrous support for the formation of the cavity, or which may no longer make it possible to form the cavity to a sufficient depth to house the electronic device. Furthermore, increasing the filler content may result in an increase in density and therefore reduced compressibility.

The presence of fillers makes it possible to improve the dimensional stability of the support and therefore improve the stability of the electronic device and of the antenna in a subsequent process of hot lamination of the fibrous support with another layer for example to form a multilayer structure.

Advantageously, the presence of synthetic fibres, of a binder and of mineral fillers at least on the surface of the support greatly facilitates insertion by pressing. The fibrous support is therefore particularly suited to the fabrication method as described hereinbelow.

In practice, the binder and the fillers exhibit a temperature behaviour and a rigidity that are sufficient, which can be quantified by a minimal picking force level, and a satisfactory level of penetration into the fibrous support which limits locally increased thicknesses on the insert.

A coating based on thermoplastic polymer binder and on mineral fillers at least on the surface of the support on which the cavity is formed imparts a higher surface energy and absorption capacity on the support, which favours the spreading and the penetration of an adhesive, and therefore the subsequent adhesion of the heat-activatable adhesive, used in the process of assembling the support of the insert with another layer, but also the subsequent assembly by cold or hot bonding of the insert with other materials, for example a cover and a flyleaf of a passport booklet, while offering sufficient security in case of attempted separation of the assembly.

In an exemplary implementation, the fibrous base of the fibrous support is bound with a synthetic polymer precipitated en masse with a Tg<20° C. and for example with a flexible polymer with a Tg of the order of −20° C., which can be precipitated in situ onto the fibres according to methods known from the prior art.

In another exemplary implementation, the fibrous base of the fibrous support is bound with a synthetic polymer with a Tg<20° C. introduced by “size press” surfacing or by impregnation and for example with a flexible polymer with a Tg of the order of 7° C., which offers both flexibility and little clogging of the “size press” or impregnating rollers. This binder may be associated with a softening agent such as urea nitrate to further increase the flexibility of the flexible support.

In another exemplary implementation, the fibrous base of the fibrous support is bound with a hydrophilic natural binder such as, for example, polyvinyl alcohol or starch, introduced by “size press” surfacing or by impregnation. This binder may have softening agent, for example glycerin, added to it, to increase the flexibility of the flexible support.

In an exemplary implementation of the invention, the support of the insert has, on at least one of its faces, a coating comprising a thermoplastic binder and mineral fillers. This binder can be selected from synthetic binders, including acrylic or vinyl polymers or copolymers, butadiene styrene or acrylonitrile butadiene styrene.

The examples of fibrous support 1 to 6 described below are particularly suited to the fabrication of the insert according to the invention.

### EXAMPLE 1

The fibrous support is fabricated on the paper machine so that the support comprises a fibrous base consisting of approximately 15% dry weight relative to the finished paper of polyamide synthetic fibres, approximately 6 mm long and approximately 1.7 dtex in diameter, and approximately 56% cellulosic fibres. The cellulosic fibres consist of 80% by number of long fibres (obtained from hardwoods) and 20% by number of short fibres (obtained from softwoods).

The support also comprises approximately 13% by weight relative to the finished paper of at least one mineral filler, introduced either at the refining stage, or later in a mixer. The mineral filler is, for example, kaolin.

The fibrous base after formation as a sheet is surfaced on the paper machine by a “size press” system. The “size press” bath contains a binder, for example polyvinyl alcohol, with a content of 4% by dry weight relative to the bath, a softening agent, for example glycerin, with a content of 15% by dry weight relative to the bath, and pigments, for example kaolin with a content of 4% by dry weight relative to the bath, i.e. a final dry extract of 23%.

During the “size press” impregnation, the paper is impregnated with approximately 40 g/m² wet bath solution, or a dry uptake of approximately 9 g/m² dry.

The fibrous base is then coated on its two faces using an air-brush coater, with a coating slip comprising 30 parts coating binder of acrylic styrene type and 100 parts of a mixture of pigments based on calcium carbonate, aluminium hydrate and sodium silicate.

The layer deposition on the support is of the order of 10 g/m² dry per face, for example.

This coated support offers good resistance to tearing by virtue of the presence of the 6 mm synthetic fibres. It also offers a certain degree of flexibility because of the presence of the synthetic fibres, the fillers in the mass and on the surface, and the glycerin.

Finally, because of the presence of the surface layer comprising at least one thermoplastic binder, it offers good suitability for the insertion of an antenna by ultrasound and, because of the presence of so-called absorbent fillers such as aluminium silicate and hydrate, an absorption capacity and a surface energy that are favourable to subsequent pasting.

### EXAMPLE 2

The fibrous support has the same formulation as in Example 1, apart from the absence of fillers in the mass and a modification of the “size press” bath which contains a coating binder, for example PVA with a content of 4% by dry weight relative to the bath, a softening agent, for example glycerin with a content of 15% by dry weight relative to the bath and an acrylic-based surface bonding product with a content of 4% by commercial weight relative to the bath.

The flexibility of the fibrous support that is obtained is a little lower than in the preceding example because of the absence of fillers but the resistance to forgery by peeling and the cohesion of the support are enhanced because the internal cohesion is higher.

### EXAMPLE 3

The fibrous support has the same formulation as in Example 1, apart from the “size press” bath which is replaced by an impregnating bath comprising only a flexible latex as binder, for example an acrylic styrene latex with a Tg equal to 5° C., which gives the support both flexibility and cohesion.

### EXAMPLE 4

The fibrous support has the same formulation as in Example 3, apart from the “size press” bath which includes urea nitrate as softening agent in addition to the flexible latex as binder for the fibrous base, hence even greater flexibility.

### EXAMPLE 5

The fibrous support has the same formulation as in Example 3, but the binder for the fibrous base is introduced by precipitation of the binder particles in situ onto the fibres, during the formation of the sheet, so as to give the support flexibility.

The binder particles are, for example, anionically fillerd latex particles, which precipitate by ionic interactions on fibres supporting cationic fillers.

With the cellulose fibres being anionically fillerd, additives such as polyamideamine-epichlorohydrin can be fixed beforehand on the fibres to modify their filler.

The latex particles with low Tg, below −10° C., give the material flexibility while not causing any clogging problems in the impregnator.

If the latex content introduced into the fibrous base is high enough, for example at least 20% by weight in the fibrous base, the surfacing of the support can be done with other surface binders, for example a PVA, and this binder will not tend to increase the rigidity of the support.

The flat fibrous support obtained according to one of the preceding examples is flexible enough to be compatible with the rigidity of the document in which it is incorporated. Such a support is capable of mechanically protecting the electronic device and the antenna from mechanical stresses such as impact, bending or twisting.

Such a fibrous support 2 is also particularly suited to the formation of a cavity by compression which is intended to receive a contactless communication electronic device.

FIG. 3a) shows the fibrous support 2 obtained according to one of the examples described above and the head 20 of an ultrasound transducer.

Generally, ultrasounds are elastic waves whose frequency is between 20 kHz and approximately 1 megahertz. The propagation of the ultrasounds in the fibrous support 2 is characterized by vibrations inducing a heating of the material and its densification. The fibrous support as described hereinabove has a compressibility rate of between 50 and 80%. Its composition is therefore especially suitable for the heating of the material and its densification does not cause random deformation of the support but forms a cavity corresponding to the head 20.

Numerous systems can produce ultrasounds. An appliance producing ultrasounds is commonly called a transducer or ultrasound converter. The technology of transducers may be based on pneumatic, electrodynamic or electrical generators. In the latter case, the properties of the magnetostrictive or piezoelectric materials are used to convert the electrical energy into an ultrasound mechanical energy. Preferably, piezoelectric materials will be used.

Conventionally, an ultrasound transducer consists of two main parts:
the ultrasound converter which is excited at its resonant frequency. It consists of piezoelectric ceramics contained between the nose and the backing block to convert the electrical energy into mechanical vibrations.
the sonotrode or compression head 20 of the transducer which transmits the mechanical vibration to the medium.

The head 20 of the ultrasound transducer is designed to form the cavity 5 in the fibrous support 2, preferably by repeated compressions at an ultrasound frequency. To this end, the head 20 is a part having a peripheral shoulder complementing that of the cavity 5 described with reference to FIG. 2.

In particular, the head of the transducer 20 is “T” shaped. The base of the “T” shape, less wide, corresponds, in dimensions, to the encapsulated chip 10 and the top of the “T” shape, wider, corresponds, in dimensions, to the connection support 11.

The ultrasound transducer (not shown) is positioned so that the head 20 is directed with the base of the “T” shape oriented towards a face of the fibrous support 2. It should be noted that the fibrous support rests on a fixed support which is not shown. The ultrasound transducer is also arranged to displace the head 20 according to a to-and-fro reciprocating movement forming vibrations at an ultrasound frequency. This movement is oriented in the direction indicated by the arrow 21 which is substantially perpendicular to the face of the fibrous support 2. The maximum displacement of the head 20 is obtained at certain resonant frequencies which depend on the geometry of the transducer. Preferably, the resonant frequency is between 20 kHz and 70 kHz and even more preferably between 20 kHz and 40 kHz.

In operation, when an electric voltage is applied to the two electrodes of the piezoelectric ceramic of the transducer, the material expands or compresses according to the orientation of the voltage relative to the polarization of the ceramic. The alternation of the electrical field causes the transition from an expansion to a compression so as to create the to-and-fro reciprocating movement.

The head 20 of the transducer therefore penetrates into the fibrous support 2 at an ultrasound frequency as is illustrated in FIG. 3b). The fibrous support 2 is thus densified by compression so as to form the cavity 5 as illustrated in FIG. 3c). The head 20 of the transducer penetrates into the fibrous support 2 to a depth that is sufficient to house the contactless communication electronic device without increasing the thickness of the insert and without passing through the fibrous support.

At the end of the process of repeated compressions, the cavity 5 that is formed corresponds perfectly and without deformation to the electronic device 3, for example a module chip. Furthermore, the fibrous support 2 is not damaged or embrittled in the area in which the cavity is formed. The contactless communication electronic device 3 is then introduced into the cavity 5 in the step illustrated by FIG. 3c), for example by means of a gripping/placement tool.

Advantageously, the formation of the cavity 5 by repeated compressions at an ultrasound frequency takes only a very short time, less than 0.5 second. Furthermore, the fabrication of the transducer is simple and inexpensive. Finally, the electronic device 3 is housed in a fibrous support formed in a single layer, that is to say avoiding a step for lamination between two layers, and without increasing the thickness of the insert.

For example, for the fabrication of an insert 1 incorporating an electronic device 330 microns thick, the fibrous support is fabricated with a thickness of 415 microns and sufficiently compressible for the method according to the invention described hereinabove to allow a cavity to be produced that corresponds to the electronic device and that has a depth of at least 330 microns.

In this exemplary embodiment, a thickness of 85 microns separates the bottom of the cavity and the face opposite to the face on which the cavity opens out. Because of the composition of the fibrous support, this opposite face is also not deformed during the cavity formation process. The opposite face has the benefit of holding the electronic device in place and protecting it.

Alternatively, in an in-line fabrication process, the fibrous support 2 may be displaced in a strip between a rotary roller and the head of a transducer. In this case, provision may be made for the rotary roller to have, on its periphery, one or more protuberances forming a “T” in cross section and for the head of the transducer to be flat. The “T”-shaped protuberances are then evenly distributed over the periphery of the rotary roller so as to form cavities in the fibrous support with a regular pitch corresponding to the desired interval between each insert 1 and/or to the dimensions of the inserts. In operation, the head of the transducer exerts repeated compressions at an ultrasound frequency on the fibrous support in a strip which is itself sandwiched between this head and the rotary roller equipped with the “T”-shaped protuberances. The result of this is that the “T” shapes penetrate into the fibrous support to continuously form cavities in the strip support. The electronic device is then deposited in the cavity for example by a gripping/placement method.

Subsequent to the insert fabrication steps illustrated in FIGS. 3a) to d), an antenna wire may be fixed to the fibrous support for example by compression, by thermocompression, by ultrasound or by bonding, using an adhesive present on the support. In the case of the use of an adhesive, the latter may be crosslinkable under UV radiation. The adhesive is then subjected to UV exposure at the same time or just before the antenna wire is unwound onto the fibrous support, the UV source being, for example, supported by a wire-depositing tool.

The technique of inserting the antenna by ultrasound allows for a penetration of the antenna wire with local melting of the matrix of the fibrous support, the insertion by pressure of the antenna wire into this support and its securing on the support after cooling. This technique may be implemented by means of a transducer and a sonotrode as were described previously.

Alternatively, the antenna may be deposited according to a silver screen-printing method on the fibrous support.

Alternatively, the cavity may be formed in the fibrous support by a thermocompression method or by stamping.

The insert according to the invention including the electronic device can then be combined with other fibrous or non-fibrous layers, for example by hot lamination, so as to form a multilayer structure.

The insert according to the invention or the multilayer structure including the insert can then be inserted into a security document or form an element of the latter.

For example, the insert is sandwiched between two other supports that are the cover and the flyleaf of the booklet in the case of a passport or two plastic or paper films in the case of a card, for example an identity card. In both cases, the insert exhibits, on its external faces, a fairly high surface energy and an absorption capacity that is sufficient to favour the assembly of the insert with other substrates by bonding. For example, one of the layers is coated with a hot-reactive adhesive, for example polyurethane-based, which will offer, after assembly with the other layer and hot lamination, all the qualities expected, notably of inviolability, to prevent any removal of the RFID device by a forger in order to use it in another document. The insert produced in this way offers good resistance to dry, hot and solvent-based forging attempts, and has good flexibility and sufficient cohesion to prevent any spontaneous delamination. Moreover, this insert exhibits the surface qualities suitable for bonding with a cold vinyl or acrylic glue as is currently used for the integration between the cover and the flyleaf of a passport booklet.

In the case of a foldable security document such as a passport with two panels for example, provision may also be made for the insert to cover the entire cover and for the electronic device 3 and the antenna 4 to be positioned so as to extend only over the part of the insert corresponding to one of the two panels. Provision may also be made for a hinge-forming groove to be formed in the middle of the insert so as to separate the two panels and facilitate the folding of the document. The groove is then formed by a transducer head of suitable dimension which penetrates into the fibrous support at an ultrasound frequency. The fibrous support is thus densified by compression to form the groove. Alternatively, the groove is formed by removing some of the material.

The invention therefore extends to any security document including the insert, such as a passport, an identity card, a driving license, an interactive playing or trading card, a payment means, notably a payment card, a purchase slip or a voucher, a transport card, a loyalty card, a service card or a subscription card.

A security document obtained in this way therefore includes at least one contactless communication electronic device whose memory can be read by a suitable reader which constitutes a so-called “third level” security element. It may, however, include other “first level” security elements and/or at least one so-called “second level” and/or “third level” security element.

The document may in particular include the following security elements, alone or in combination:
luminous colourants and/or pigments and/or interferential pigments and/or liquid crystal pigments, notably in printed form or mixed with at least one constituent layer of the document,
photochromic or thermochromic components, colourants and/or pigments, notably in printed form or mixed with at least one constituent layer of the document,
an ultraviolet (UV) absorber, notably in coated form or mixed with at least one constituent layer of the document,
a specific light-collecting material, for example of the “waveguide” type, for example a luminous light-collecting material such as the polycarbonate-based polymer films marketed by the company BAYER under the trade name LISA®,
an interferential multilayer film,
a structure with variable optical effects based on interferential pigments or liquid crystals,
a birefringent or polarizing layer,
a diffraction structure,
an embossed image,
means producing a “Moire effect”, such an effect being able, for example, to reveal a pattern produced by the superposition of two security elements on the document, for example by the convergence of lines of two security elements,
a partially reflecting refractive element,
a transparent lenticular grating,
a lens, for example a magnifying glass,
a coloured filter,
another metallized foil, goniochromatic or holographic,
a layer with a variable optical effect based on interferential pigments or liquid crystals,
a flat security element of relatively small size such as a flake, visible or not visible, notably luminous, with or without electronic device,
particles or agglomerates of pigment particles or colourants of HI-LITE type, visible or not visible, notably luminous,
security fibres, notably metallic, magnetic (with soft and/or hard magnetism), or absorbent, or that can be excited with the ultraviolet, the visible or the infrared, and in particular the near infrared (NIR), bands,
an automatically readable security measure having specific and measurable luminescence (for example fluorescence, phosphorescence), light absorption (for example ultraviolet, visible or infrared), Raman activity, magnetism, microwave interaction, X-ray interaction or electrical conductivity characteristics,
forge-prevention reagents, for example dipyridyl with ferric ions which, on a forging attempt by a reducer, are reduced to ferrous ions and reveal a red colour,
a reagent such as potassium iodate that can form a visible and coloured mark on a forging attempt.

One or more security elements as defined above may be present in the document and/or in one or more constituent layers of the document or in one or more security elements incorporated in the document and/or in one or more constituent layers of the document, such as, for example, a wire, a fibre or flake.

At least one of the constituent layers of the document may also include a first level security element such as a watermark or a pseudo-watermark at least partially superposed on a translucent region of the document.

The expression “including” or “comprising” should be understood to be synonymous with “including at least one” or “comprising at least one”, unless otherwise specified.

What is claimed is:

1. An insert adapted for insertion into a security document comprising:
a fibrous support consisting of a single layer of synthetic fibers, said fibrous support having a first surface and a second surface opposite said first surface, said first surface containing a cavity; and
a contactless communication electronic device housed within said cavity;
wherein said cavity comprises a peripheral shoulder adapted to house said electronic device without increasing the thickness of said insert.

2. The insert according to claim 1, further comprising:
said electronic device being a module chip having a connection support positioned in said peripheral shoulder, and an encapsulated chip positioned at the bottom of said cavity resting on said connection support establishing a connection between said chip and an antenna.

3. The insert according to claim 2, further comprising said module chip being a micromodule chip of type selected from the group consisting of MOA2, MOB2, MOA4, MOB4, MOA6, MOB6, MCC2, MCC8, CID, Cubit, IOA2, EOA2, EOA8, EOA9, FCP3, and NSL-1.

4. The insert according to claim 2, further comprising:
a wired or screen-printed antenna positioned on said first face of said fibrous support, said antenna having two ends connected to said connection support for a contactless communication.

5. The insert according to claim 1, further comprising said fibrous support being formed by at least 30% natural fibers, wherein said natural fibers are cellulosic fibers or cotton fibers with a lower proportion of short fibers than long fibers.

6. The insert according to claim 1, further comprising said fibrous support having a binder selected from thermoplastic polymers with a glass transition temperature of between −25° C. and 40° C.

7. The insert according to claim 6, further comprising said binder being selected from the group consisting of a butadiene styrene copolymer, an acrylic polymer, a vinyl acetate and their copolymers, a latex, a starch compound, a mineral filler compound, and combinations thereof.

8. The insert according to claim 1, further comprising said fibrous support having a softening agent selected from the group consisting of glycerin, urea, and urea nitrate.

9. The insert according to claim 1, further comprising said fibrous support being composed between 8 and 15% by weight of said synthetic fibers.

10. The insert according to claim 9, further comprising said synthetic fibers being of a thermoplastic material selected from the group consisting of a polyamide, a polyester, a polyolefin, and combinations thereof.

11. Insert according to claim 1, further comprising said fibrous support having a mineral filler selected from the group consisting of talc, kaolin, aluminum hydrate, titanium dioxide, sodium silicate, and combinations thereof, said filler preferably being an absorbent filler having an absorption capacity greater than or equal to 30 ml/100 g.

12. A security document containing an insert, said insert comprising a fibrous support consisting of a single layer of synthetic fibers, said fibrous support having a first surface and a second surface opposite said first surface, said first surface containing a cavity, and a contactless communication electronic device housed within said cavity, wherein said cavity comprises a peripheral shoulder adapted to house said electronic device without increasing the thickness of said insert, said security document being selected from the group consisting of a passport, an identity card, a driving license, an interactive playing card, a trading card, a payment card, a purchase slip, a purchase voucher, a transport card, a loyalty card, a service card, and a subscription card.

13. A method of fabricating an insert intended for insertion into a security document, said method comprising the steps:
providing a fibrous support comprising synthetic fibers;
forming a cavity in said support by compression utilizing a tool having a shape such that the resulting cavity has an opening on a single face of said fibrous support and a peripheral shoulder; and
housing an electronic device in said cavity without increasing the thickness of the insert.

14. The method according to claim 13, wherein the step for forming said cavity in said fibrous support is performed by repeated compressions at an ultrasound frequency.

15. The method according to claim 13, characterized in that the step for forming said cavity in said support is performed by thermocompression or stamping.

16. The method according to claim 13, further comprising the steps of:
providing a module chip having a connection support and an encapsulated chip resting on said connection support establishing a connection between said module chip and an antenna;
placing said connection support in said peripheral shoulder of the cavity; and
placing said encapsulated chip at the bottom of said cavity.

17. The method according to claim 13, further comprising the step of placing a wired or screen-printed antenna on said face of said fibrous support, said antenna having two ends connected to the connection support for a contactless communication.

18. The method according to claim 13, wherein said fibrous support contains at least 30% natural fibers, said natural fibers being selected from the group consisting of cellulosic fibers and cotton fibers with a lower proportion of short fibers than long fibers.

19. The method according to claim 13, wherein said fibrous support contains a binder, said binder being selected from the group consisting of a thermoplastic polymer with a glass transition temperature of between −25° C. and 40° C., a butadiene styrene copolymer, an acrylic polymer, a vinyl acetate, and copolymers of vinyl acetate, a latex, a starch compound, a mineral filler compound, and combinations thereof.

20. The method according to claim 13, wherein said fibrous support contains a softening agent selected from the group consisting of glycerin, urea, and urea nitrate.

21. The method according to claim 13, wherein said fibrous support is composed between 8 and 15% by weight of synthetic fibers.

22. The method according to claim 21, wherein said synthetic fibers contain thermoplastic material selected from the group consisting of a polyamide, a polyester, a polyolefin, and composition thereof.

23. The method according to claim 13, wherein said fibrous support contains a mineral filler selected from the group consisting of calcium, talc, kaolin, aluminum hydrate, titanium dioxide, sodium silicate, and combinations thereof, said filler preferably being an absorbent filler having an absorption capacity greater than or equal to 30 ml/100 g.
